(19) United States
(12) Patent Application Publication
(10) Pub. No.: US 2016/0088498 A1
(43) Pub. Date: Mar. 24, 2016

(54) UNMANNED AERIAL VEHICLE FOR ANTENNA RADIATION CHARACTERIZATION

(71) Applicant: KING FAHD UNIVERSITY OF PETROLEUM AND MINERALS, Dhahran (SA)

(72) Inventor: MOHAMMAD S. SHARAWI, DHAHRAN (SA)

(21) Appl. No.: 14/490,627

(22) Filed: Sep. 18, 2014

(51) Int. Cl. H04W 24/08; B64C 39/02; G01R 29/10

(52) U.S. Cl. CPC H04W 24/08; G01R 29/10; B64C 39/024; B64C 2201/122

(57) ABSTRACT

The unmanned aerial vehicle for antenna radiation characterization is an unmanned aerial vehicle having a propulsion system and a transceiver. Control signals are transmitted from a base station to position the unmanned aerial vehicle adjacent an antenna of interest. The unmanned aerial vehicle for antenna radiation characterization further includes a signal strength antenna for receiving an antenna signal generated by the antenna of interest for calculating or determining the received signal strength of the antenna signal. A received signal strength signal is then transmitted back to the base station, in real time. The received signal strength signal is representative of a set of received signal strengths of the antenna signal corresponding to a set of three-dimensional measurement coordinates such that the received signal strength signal represents a three-dimensional radiation pattern associated with the antenna of interest.

### BACKGROUND OF THE INVENTION

1. Field of the Invention

The present invention relates to characterization of antenna radiation patterns, and particularly to an unmanned aerial vehicle for antenna radiation characterization.

2. Description of the Related Art

Characterization of antenna radiation is used to develop radiation patterns of transmitted signals from an antenna, or antenna array, of interest. Analyses of these radiation patterns are used to show actual radiation performances of antennas after they are placed in their final fixed positions, such as tower antennas, antennas mounted on the sides of buildings, or within buildings, or the like. Typically, such patterns are developed by measuring received signal strength about the antenna using a mobile device. However, such mobile devices are typically carried by ground vehicles or the like, thus generating only a two-dimensional approximation of the true three-dimensional radiation pattern.

Also, characterization of antennas is typically performed indoors using anechoic chambers where an antenna under test is rotated around two axes to measure its three dimensional (3D) radiation pattern. For larger antennas or antennas on movable objects (e.g., automobiles), large outdoor antenna ranges typically are used where an antenna under test and a calibrated test antenna are used to measure the received signal levels at different angles to determine its 3D special behavior. However, such approaches generally require bringing the antenna under test to a testing facility and typically do not capture the effect of its surroundings on its actual performance when placed in the actual location or site where it can be surrounded by structures, buildings, trees, etc., for example.

Although unmanned aerial vehicles, such as unmanned drones and the like, are known, such vehicles typically only have transceivers adapted solely for navigational purposes. It would be desirable to provide the three-dimensional positioning of an unmanned aerial vehicle with a received signal strength indicator for mapping true three-dimensional radiation patterns of antennas in real time. Thus, an unmanned aerial vehicle for antenna radiation characterization addressing the aforementioned problems is desired.

### SUMMARY OF THE INVENTION

The unmanned aerial vehicle for antenna radiation characterization is an unmanned aerial vehicle having a propulsion system and a transceiver. Control signals are transmitted from a base station to position the unmanned aerial vehicle adjacent an antenna of interest. The unmanned aerial vehicle for antenna radiation characterization further includes a signal strength antenna for receiving an antenna signal generated by the antenna of interest for calculating the received signal strength of the antenna signal. A received signal strength signal is then transmitted back to the base station, in real time. The received signal strength signal is representative of a set of received signal strengths of the antenna signal corresponding to a set of three-dimensional measurement coordinates such that the received signal strength signal represents a three-dimensional radiation pattern associated with the antenna of interest.

These and other features of the present invention will become readily apparent upon further review of the following specification.

### BRIEF DESCRIPTION OF THE DRAWINGS

FIG. 1 is an environmental view of an unmanned aerial vehicle for antenna radiation characterization according to the present invention.

FIG. 2 is a block diagram showing a controller of the unmanned aerial vehicle for antenna radiation characterization.

FIG. 3 is a flowchart of an embodiment of a process for antenna radiation characterization according to the present invention.

FIG. 4 is a diagrammatic illustration of an example of an antenna directive pattern for antenna radiation characterization according to embodiments of a process for antenna radiation characterization according to the present invention.

Unless otherwise indicated, similar reference characters denote corresponding features consistently throughout the attached drawings.

### DETAILED DESCRIPTION OF THE PREFERRED EMBODIMENTS

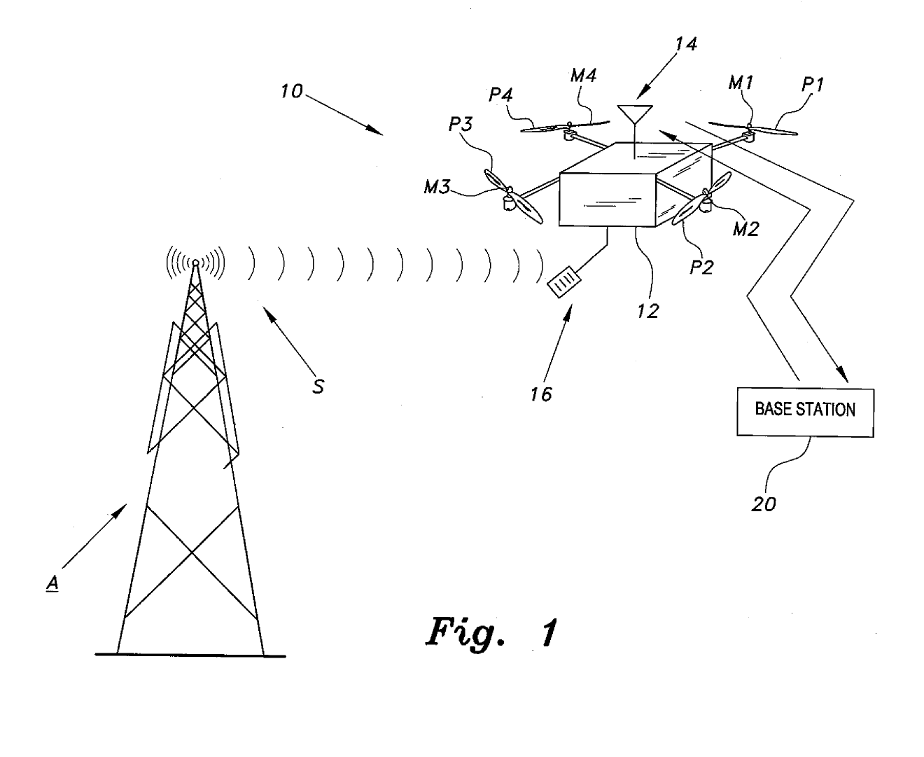

The unmanned aerial vehicle (UAV) for antenna radiation characterization 10 (“UAV 10”) is an unmanned aerial vehicle adapted for sensing and mapping received signal strength of a signal transmitted from an antenna for three-dimensional characterization of the antenna signal, such as can use a radio frequency (RF) type system. Embodiments of the UAV for antenna radiation characterization provide an antenna radiation pattern measurement system that utilizes a UAV, such as the UAV 10, to fly in the area around a stationary antenna and collect the data to determine the radiation characteristics and a shape of the stationary antenna. As shown in FIG. 1, the unmanned aerial vehicle for antenna radiation characterization 10 is a conventional unmanned aerial vehicle having a transceiver antenna 14, for communicating with a base station 20, and a signal strength antenna 16 for sensing and receiving a signal S transmitted from antenna A.

In FIG. 1, the unmanned aerial vehicle for antenna radiation characterization 10 is shown as a conventional quad-rotor unmanned aerial vehicle having main body 12 with four stabilizing and propulsion motors M1, M2, M3 and M4 for driving corresponding propellers P1, P2, P3 and P4. Such quad-rotor unmanned aerial vehicles are well known in the art, and examples of such are shown in U.S. Patent Application Publications U.S. 2014/0138477 A1 and U.S. 2012/0271491 A1, each of which is hereby incorporated by reference in its entirety. However, it should be understood that any suitable type of controllable unmanned aerial vehicle may be utilized, and that the quad-rotor design in FIG. 1 is shown for exemplary purposes only.

A ground station, such as the base station 20, such as can be a laptop computer or other suitable personal computer, can be used to configure and control the flying and data processing received from the flying UAV 10, such as after mounting a suitable signal strength antenna 16 for the RSS radiation pattern measurements. The base station 20 can include a suitable transceiver, which can be any suitable type of radio frequency (RF) or wireless transceiver, to send and receive information, data and signals, and can include any suitable type of controller or processor, such as a microprocessor or a processor associated with, or incorporated into, any suitable type of computing device, such as, a personal computer, a programmable logic controller (PLC), application specific integrated circuit (ASIC) or the like. The processor of the base station 20 also is associated with a memory to store program instructions, information and data related to antenna radiation characterization, as described herein, such as a non-transitory computer readable storage memory, an optical disk, a magneto-optical disk, and/or a semiconductor memory (for example, RAM, ROM, etc.), for example. In use, base station 20 transmits a command to the unmanned aerial vehicle for antenna radiation characterization 10 to fly to the coordinates of an antenna A of interest. It should be understood that the antenna A of FIG. 1 is shown for exemplary purposes only, and that measurements of any type of transmitting antenna or antenna array can be taken.

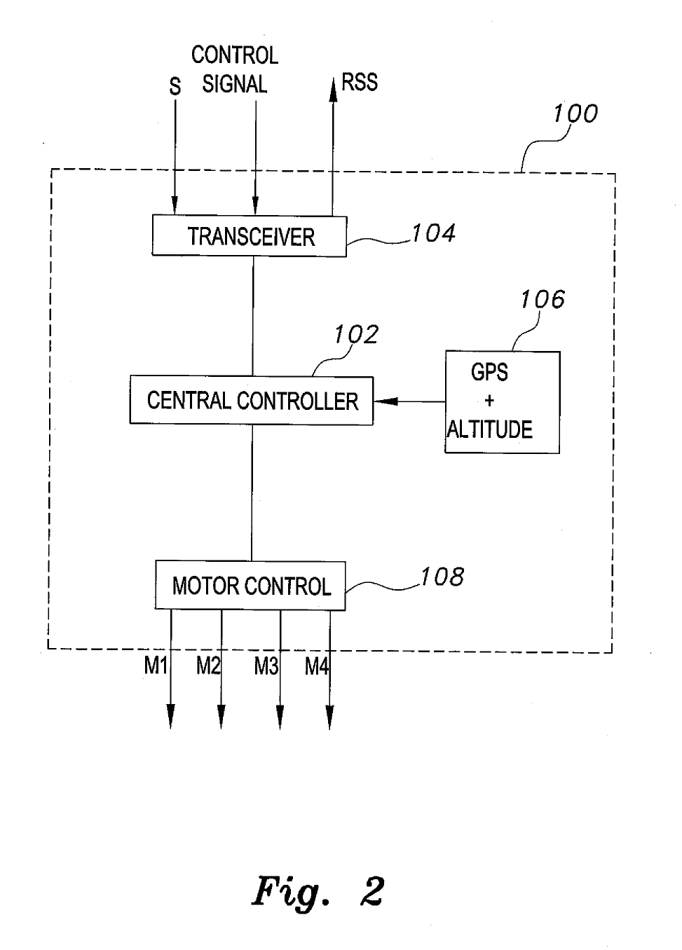

As shown in FIG. 2, an onboard controller 100 of the unmanned aerial vehicle for antenna radiation characterization 10 includes a locating system 106, such as the global positioning system (GPS) or the like, coupled with an altimeter or the like, allowing for instantaneous orientation and location-finding of the unmanned aerial vehicle for antenna radiation characterization 10 in three dimensions (i.e., latitude, longitude and altitude). The control signals from base station 20 are received by transceiver antenna 14 of a transceiver assembly 104, which can be any suitable type of radio frequency (RF) or wireless transceiver.

Transceiver 104 is in communication with a central controller 102, which can be any suitable type of controller or processor, such as a microprocessor or a processor associated with, or incorporated into, any suitable type of computing device, such as, a personal computer, a programmable logic controller (PLC), application specific integrated circuit (ASIC) or the like. The central controller 102, is associated with a memory of the onboard controller 100 to store program instructions, information and data related to antenna radiation characterization, as described herein, such as a non-transitory computer readable storage memory, an optical disk, a magneto-optical disk, and/or a semiconductor memory (for example, RAM, ROM, etc.), for example. Central controller 102 transmits control signals to a motor controller 108 for controlling motors M1, M2, M3 and M4 for controlling the flight of the unmanned aerial vehicle for antenna radiation characterization 10, as is conventionally known.

Once the unmanned aerial vehicle for antenna radiation characterization 10 reaches antenna A, it flies, under control, in a path about the antenna A to take measurements of received signal strength (RSS) linked with particular three-dimensional coordinates about antenna A in order to map or characterize the signal S of antenna A in three dimensions about antenna A. The UAV 10 covers the path around the antenna A of interest, as can be located in its normal location, and the radiation pattern of antenna A of interest, as can be an in-situ antenna, for example, is recorded based on the measured RSS level of signal S around the site of antenna A. Within the control electronics of the UAV 10, such as on the onboard controller 100, controlling circuitry and programs, as stored in the associated memory thereon, can be used to calculate or determine, such as by or in associated with the central controller 102, the location of the UAV 10 in 3D space in terms of altitude, longitude and latitude.

Desirably, the tilt angle of the signal strength antenna 16 can be controlled by a separate motor, actuator or the like, under control of the central controller 102, to achieve angles which typically cannot easily be attained by the regular relatively stable controlled flight of the unmanned aerial vehicle. Central controller 102, thus, controls the wide bandwidths for radiation pattern measurements by, desirably, both controlling tilt of the signal strength antenna 16, as well as the three-dimensional flight of the UAV 10.

The UAV 10 can be controlled to make small angle tilts and further the signal strength antenna 16 can be moved with relatively steeper tilts as can be required by the RSS measurement under consideration, for example. Also, steeper tilts of the UAV 10 can also be made along with movements of the signal strength antenna 16 to cover relatively difficult locations within an in-situ measurement, for example. Also, the signal strength antenna 16 can be mounted on a mechanically controlled movable platform to allow the antenna beam to be further tilted for various angles, such as those that are not typically covered by the UAV 10 tilts. Also, within the electronics of the UAV 10, such as those associated with the onboard controller 100, a programmable received signal strength (RSS) module can be used to cover relatively wide bandwidths that the platform, such as a mechanically controlled movable platform, can cover in its radiation pattern measurements, for example.

Techniques for measuring received signal strength (RSS) are well known in the art. Examples of such techniques are shown in U.S. Pat. No. 8,457,569 B2 and in U.S. Patent Application Publications U.S. 2012/0064894 A1 and U.S. 2011/0207413 A1, each of which is hereby incorporated by reference in its entirety. It should be understood that any of various suitable type of RSS sensing techniques can be utilized, and that signal strength antenna 16 can be any suitable type of antenna adapted for RSS sensing and for RSS measurements, such as a narrow half-power-beam-width (HPBW) directive antenna or the like, for example.

The three-dimensional RSS measurements are transmitted, via transceiver 104 and transceiver antenna 14, to the base station 20 for recordation and analysis. The transceiver antenna 14 relays the RSS measurements in terms of coordinates and measured signal levels (RSS) back to the base station 20, such as a ground station or laptop computer, for example. The onboard controller 100 typically includes hardware platforms, as well as various positioning and data transfer algorithms, for the antenna radiation characterization. The coordinates of the UAV 10, as well as the measured RSS levels are relayed back to the ground station, such as the base station 20, for further processing. The RSS signal and corresponding three-dimensional coordinates of the measurement are transmitted back to base station 20 in real time.

The base station 20 calculates or determines the radiation pattern of the antenna A based on the received RSS levels. In this regard, the received signal strength signal is representative of a set of received signal strengths of the antenna signal S of antenna A corresponding to a set of three-dimensional measurement coordinates such that the received signal strength signal represents a three-dimensional radiation pattern associated with the antenna A of interest. At base station 20, the received data can be collated, aggregated and analyzed to develop a three-dimensional radiation pattern characteristic of antenna A. As is well known in the art, such analyses of radiation patterns are used to show actual radiation performances of antennas after they are placed in their final positions on towers, sides of buildings and within buildings, for example, as well as various effects of the surrounding environment on the antenna of interest, such as antenna A, can be also be observed, understood and analyzed, for example.

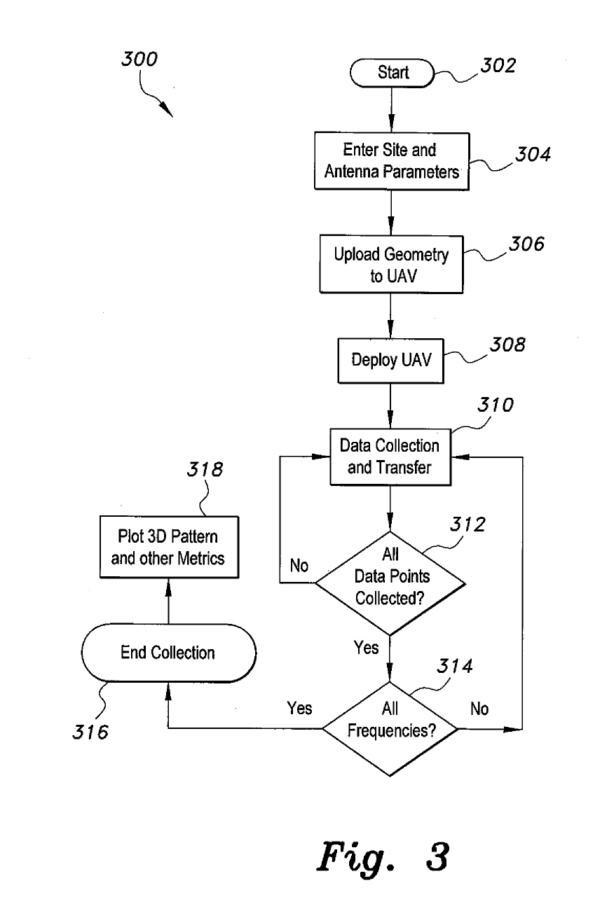

FIG. 3 is a flowchart of an embodiment of a process for antenna radiation characterization according to the present invention. The process starts at step 302. From step 302 the process proceeds to step 304 where the UAV 10 is configured by entering or transmitting to the base station 20 the site and antenna parameters, such as an antenna frequency range and a required geometry to be covered by the UAV 10. Then at step 306, the base station 20 uploads to the UAV 10 the required geometry and antenna parameters, such as the frequency range. The process proceeds to step 308 where the UAV 10 is deployed and then proceeds to step 310 to collect the data on the antenna A of interest and to transfer the collected data.

At step 312 it is determined whether all the data points for the antenna A of interest have been collected. If not, the process returns to step 310. If so, the process then proceeds to step 314 to determine whether data has been collected for all of the frequencies of the frequency range of interest. If not, the process returns to step 310. If so, the process then proceeds to step 316 to end collection. From step 316, the process then proceeds to step 318 where a ground station, such as the base station 20, processes the collected data and arranging the data points to plot or illustrate a 3D pattern of the antenna directive pattern and other metrics of interest for the antenna A of interest. The process then ends and the UAV 10 can be placed out of service or can then, or at another time, return to step 302 for data collection as to a same or another antenna.

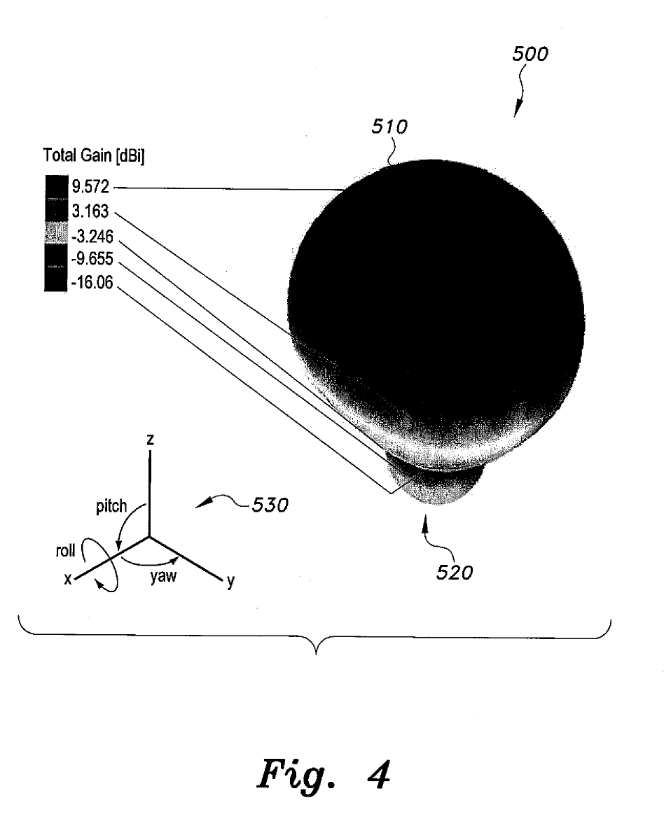

Referring now to FIG. 4, an example of an antenna directive pattern 500 for antenna radiation characterization in embodiments of a process for antenna radiation characterization is illustrated, such as provided by the embodiment of the process illustrated and described with respect to FIG. 3 above. In the antenna directive pattern 500, a front side 510 of the antenna directive pattern (main beam) has a maximum directive gain of approximately 9.572 dBi, for example, with the directive gain of other areas of the antenna directive pattern 500 being indicated by the lines from the “Total Gain” scale to corresponding portions of the antenna directive pattern 500. As indicated from FIG. 4, a back lobe 520 of the antenna directive pattern 500 has a relatively less directive gain from that of the front side 510. Such a radiation pattern can be obtained from a low profile printed antenna structure of microstrip antennas with wide bandwidth to cover several frequencies of interest, for example.

Also, FIG. 4 illustrates a coordinate system, such as coordinate system 530, as can be used in conjunction with a measured RS S of the antenna A of interest or under test. The coordinate system 530 can be used in relation to the UAV 10's 3D coordinates, the UAV 10's attitude, and the known radiation pattern of the UAV 10's signal strength antenna 16, as can be used to compute or determine a 3D radiation pattern of the antenna under test, for example. The way the UAV 10 tilts to cover various angles in space, such as for a relatively full 3D coverage of RS S measurements, can be indicated with the three dimensional coordinate system 530 indicating the roll, pitch and yaw of the flying vehicle, for example.

Embodiments of an unmanned aerial vehicle for antenna radiation characterization can provide a relatively low cost, in-location (in-situ) antenna radiation pattern measurement system that utilizes a UAV. The system can operate at various frequency ranges after configuring the on-vehicle antenna and the electronics, such as by interchangeable modular components to cover a corresponding frequency of interest. The UAV can use onboard sensors in addition to ground references to determine and record the UAV's position, altitude, and attitude continuously, substantially continuously, periodically, or at various predetermined times, for example.

The antenna characterization is performed by installing the appropriate signal strength antenna, such as signal strength antenna 16, onto the UAV, such as the UAV 10, and then flying it, autonomously or under remote control, in the 3-dimensional (3D) space around a stationary antenna under test. Measured receive signal strength (RSS) is recorded throughout the test as a function of the UAV's 3D coordinates and its attitude, for example. The data can be collected and provided to the onboard controller 100 and then provided to the base station 20, such as a portable computing device, where the radiation pattern strength is further analyzed. From the measured RSS, the UAV's 3D coordinates, the UAV's attitude, and the known radiation pattern of the UAV's signal strength antenna, a 3D radiation pattern of the antenna under test can be computed or determined.

Embodiments of a 3D antenna radiation pattern measurement system utilizing UAVs can operate over several frequency bands, and can conduct antenna radiation pattern measurements in an actual deployment location of the antenna, as can take into consideration its surroundings, as can enable a relatively more accurate representation of the radiation behavior being measured. As described, the collected data is then relayed for processing according to the altitude and location of the UAV and the power level received, such as from the on-board radio frequency (RF) receiver.

It is to be understood that the present invention is not limited to the embodiments described above, but encompasses any and all embodiments within the scope of the following claims.

I claim:

1. An unmanned aerial vehicle for antenna radiation characterization, comprising:
an unmanned aerial vehicle having a propulsion system and a transceiver, whereby said transceiver receives control signals from a base station to position the unmanned aerial vehicle adjacent an antenna of interest;
a signal strength antenna mounted on the unmanned aerial vehicle for receiving an antenna signal generated by the antenna of interest; and
means for determining a received signal strength of the antenna signal, wherein the transceiver transmits a received signal strength signal to the base station, the received signal strength signal being representative of a set of received signal strengths of the antenna signal corresponding to a set of three-dimensional measurement coordinates such that the received signal strength signal represents a three-dimensional radiation pattern associated with the antenna of interest.

2. The unmanned aerial vehicle for antenna radiation characterization as recited in claim 1, further comprising:
a transceiver antenna mounted on the unmanned aerial vehicle and being in communication with the transceiver.

3. The unmanned aerial vehicle for antenna radiation characterization as recited in claim 2, wherein the signal strength antenna is selectively and controllably tiltable.

4. The unmanned aerial vehicle for antenna radiation characterization as recited in claim 1, wherein the signal strength antenna is selectively and controllably tiltable.

5. The unmanned aerial vehicle for antenna radiation characterization as recited in claim 1, wherein the signal strength antenna is selectively and controllably tiltable to control a bandwidth for radiation pattern measurements for the antenna signal generated by the antenna of interest.

6. The unmanned aerial vehicle for antenna radiation characterization as recited in claim 1, wherein the three-dimensional radiation pattern associated with the antenna of interest is determined based on one or more of the three dimensional coordinates of the unmanned aerial vehicle, an attitude of the unmanned aerial vehicle, and a known radiation pattern of the signal strength antenna.

7. A method for antenna radiation characterization, comprising the steps of:
transmitting control signals from a base station to an unmanned aerial vehicle to position the unmanned aerial vehicle adjacent an antenna of interest;
receiving an antenna signal generated by the antenna of interest;
determining a received signal strength of the antenna signal; and
transmitting a received signal strength signal to the base station, the received signal strength signal being representative of a set of received signal strengths of the antenna signal corresponding to a set of three-dimensional measurement coordinates such that the received signal strength signal represents a three-dimensional radiation pattern associated with the antenna of interest.

8. The method for antenna radiation characterization as recited in claim 7, further comprising the step of:
selectively and controllably tilting a signal strength antenna of the unmanned aerial vehicle to receive the antenna signal generated by the antenna of interest.

9. The method for antenna radiation characterization as recited in claim 7, further comprising the step of:
selectively and controllably tilting a signal strength antenna of the unmanned aerial vehicle to receive the antenna signal generated by the antenna of interest to control a bandwidth for radiation pattern measurements for the antenna signal generated by the antenna of interest.

10. The method for antenna radiation characterization as recited in claim 7, wherein the three-dimensional radiation pattern associated with the antenna of interest is determined based on one or more of the three dimensional coordinates of the unmanned aerial vehicle, an attitude of the unmanned aerial vehicle, and a known radiation pattern of a signal strength antenna mounted on the unmanned aerial vehicle for receiving the antenna signal generated by the antenna of interest.

11. The method for antenna radiation characterization as recited in claim 10, further comprising the step of:
selectively and controllably tilting the signal strength antenna of the unmanned aerial vehicle to receive the antenna signal generated by the antenna of interest.

12. The method for antenna radiation characterization as recited in claim 10, further comprising the step of:
selectively and controllably tilting the signal strength antenna of the unmanned aerial vehicle to receive the antenna signal generated by the antenna of interest to control a bandwidth for radiation pattern measurements for the antenna signal generated by the antenna of interest.
